(19) United States
(12) Patent Application Publication
(10) Pub. No.: US 2023/0167535 A1
(43) Pub. Date: Jun. 1, 2023

(54) FINE METAL MASK AND MANUFACTURING METHOD THEREOF

(71) Applicant: Darwin Precisions Corporation, Hsinchu County (TW)

(72) Inventors: Kuan-Chieh FANG, Hsinchu County (TW); Chi-Wei LIN, Hsinchu County (TW)

(21) Appl. No.: 17/669,395

(22) Filed: Feb. 11, 2022

(30) Foreign Application Priority Data
Dec. 1, 2021 (TW) 110144888

(51) Int. Cl. C23C 14/04; H01L 51/56; C23C 14/24; G03F 7/00

(52) U.S. Cl. CPC C23C 14/042; H01L 51/56; C23C 14/24; G03F 7/0015

(57) ABSTRACT

A fine metal mask includes a plate including a first and a second surfaces. The first surface has a first inner edge defining a first opening. The second surface has a second inner edge defining a second opening communicated with the first opening. The plate includes a first and a second curved surfaces respectively connecting the first surface inside the first opening and the second surface inside the second opening. The first and the second curved surfaces connect with a third inner edge defining a third opening smaller than the first and the second openings. The third inner edge includes a first straight edge, a second straight edge and a circular edge. The first and the second straight edges form an included angle. The circular edge has a radius smaller than or equal to 15 microns and connects between the first and the second straight edges.

### RELATED APPLICATIONS

This application claims priority to Taiwanese Application Serial Number 110144888 filed Dec. 1, 2021, which is herein incorporated by reference.

### BACKGROUND

### Technical Field

The present disclosure relates to fine metal masks and the method of manufacturing these fine metal masks.

### Description of Related Art

With the continuous improvement of the living standards nowadays, application of electronic products has become an indispensable part of our lives. Among different choices, the electronic products with display screens have become more and more popular. Correspondingly, with the rapid advancement of technology, the demand and expectation of people to the electronic products has also been increasing.

As a result, under the condition that the production cost to be maintained, the way to enhance the display quality of display devices is undoubtedly one of the important issues which the industry highly concerns.

### SUMMARY

A technical aspect of the present disclosure is to provide a fine metal mask, which can make the shape of each of the pixels formed on a base plate of a display by evaporation become clearer and sharper, such that the display quality of the display can be effectively enhanced.

According to an embodiment of the present disclosure, a fine metal mask includes a plate. The plate includes a first surface and a second surface opposite to the first surface. The first surface has at least one first inner edge surrounding and defining a first opening. The second surface has at least one second inner edge surrounding and defining a second opening. The second opening corresponds to and communicates with the first opening. The plate further includes at least one first curved surface and at least one second curved surface. The first curved surface is located inside the first opening and is connected with the first surface. The second curved surface is located inside the second opening and is connected with the second surface. The plate has at least one third inner edge. The first curved surface and the second curved surface are connected with the third inner edge. The third inner edge surrounds and defines a third opening. The third opening is smaller than the first opening and the second opening. The third inner edge includes a first straight edge, a second straight edge and a circular edge. The first straight edge and the second straight edge together form an included angle. The circular edge is connected between the first straight edge and the second straight edge. The circular edge has a radius less than or equal to 15 microns.

In one or more embodiments of the present disclosure, the second opening is bigger than the first opening. The third inner edge and the first inner edge have a height therebetween in a first direction perpendicular to the first surface. The height is less than or equal to 3 microns. The third inner edge and the first inner edge have a width therebetween in a second direction parallel with the first surface. The width is less than or equal to 2 microns.

In one or more embodiments of the present disclosure, the third inner edge is closer to the first surface than to the second surface.

In one or more embodiments of the present disclosure, the first surface and the second surface define a thickness therebetween. A range of the thickness is between 20 microns and 50 microns.

In one or more embodiments of the present disclosure, the third inner edge is of a rectangular shape.

In one or more embodiments of the present disclosure, the third inner edge is of a polygonal shape.

In one or more embodiments of the present disclosure, a material of the plate is iron-nickel alloy.

A technical aspect of the present disclosure is to provide a method of manufacturing a fine metal mask, which can manufacture a fine metal mask having an opening in a simple and easy manner, in which the radius of the opening at the corner is less than or equal to 15 microns, facilitating the shape of each of the pixels formed on a base plate of a display by evaporation to become clearer and sharper, such that the display quality of the display can be effectively enhanced.

According to an embodiment of the present disclosure, a method of manufacturing a fine metal mask includes the following procedures: (1) providing a sheet including a first surface and a second surface opposite to the first surface; (2) disposing a first resist film on the first surface; (3) disposing a first exposure mask on the first resist film, the first exposure mask having at least one first pattern, the first pattern having a first edge surrounding and corresponding to a first etching region on the sheet, the first edge including a first straight edge, a second straight edge and a third straight edge, the first straight edge and the second straight edge together forming a first included angle, the third straight edge being connected between the first straight edge and the second straight edge, the third straight edge having a length less than or equal to 8 microns; (4) disposing a second resist film on the second surface; and (5) disposing a second exposure mask on the second resist film, the second exposure mask having at least one second pattern, the second pattern being bigger than the first pattern and having a second edge surrounding and corresponding to a second etching region on the sheet, the second etching region corresponding to the first etching region, the second edge including a fourth straight edge, a fifth straight edge and a sixth straight edge, the fourth straight edge and the fifth straight edge together forming a second included angle, the sixth straight edge being parallel with the third straight edge and connected between the fourth straight edge and the fifth straight edge, the sixth straight edge and the third straight edge being separated by a distance in a direction parallel with the first surface, the distance being larger than 5 microns and less than 30 microns inclusively.

In one or more embodiments of the present disclosure, the first straight edge and the fourth straight edge are parallel with each other. The second straight edge and the fifth straight edge are parallel with each other.

In one or more embodiments of the present disclosure, the first included angle is equal to the second included angle.

In one or more embodiments of the present disclosure, the manufacturing method further includes the following procedures: (1) exposing the first resist film through the first exposure mask to develop the first resist film and form the first pattern on the first resist film, so as to expose the first etching region; and (2) exposing the second resist film through the second exposure mask to develop the second resist film and form the second pattern on the second resist film, so as to expose the second etching region.

In one or more embodiments of the present disclosure, the manufacturing method further includes the following procedures: (1) etching the first surface to form a first opening at the first etching region; and (2) etching the second surface to form a second opening at the second etching region, the first opening being mutually communicated with the second opening.

In one or more embodiments of the present disclosure, etching the second surface to form the second opening includes the following procedure: forming an inner edge on the sheet, in which the inner edge is closer to the first surface than to the second surface, and the inner edge surrounds and defines a third opening smaller than the first opening and the second opening.

In one or more embodiments of the present disclosure, the first surface and the second surface define a thickness therebetween. A range of the thickness is between 20 microns and 50 microns.

In one or more embodiments of the present disclosure, a material of the sheet is iron-nickel alloy.

A technical aspect of the present disclosure is to provide a fine metal mask, which can make the shape of each of the pixels formed on a base plate of a display by evaporation become clearer and sharper, such that the display quality of the display can be effectively enhanced.

According to an embodiment of the present disclosure, a fine metal mask includes a plate. The plate includes a first surface and a second surface opposite to the first surface. The first surface has at least one first hexagonal inner perimeter surrounding and defining a first opening. The second surface has at least one second hexagonal inner perimeter surrounding and defining a second opening. The second opening corresponds to and communicates with the first opening. The plate further includes at least one first curved surface and at least one second curved surface. The first curved surface is located inside the first opening and is connected with the first surface. The second curved surface is located inside the second opening and is connected with the second surface. The plate has at least one third hexagonal inner perimeter. The first curved surface and the second curved surface are connected with the third hexagonal inner perimeter. The third hexagonal inner perimeter surrounds and defines a third opening. The third opening is smaller than the first opening and the second opening. The third hexagonal inner perimeter includes at least one first straight edge, at least one second straight edge and at least one circular edge. The first straight edge and the second straight edge together form an included angle of 120 degrees. The circular edge is connected between the first straight edge and the second straight edge. The circular edge having a radius less than or equal to 15 microns.

In one or more embodiments of the present disclosure, the second opening is bigger than the first opening. The third hexagonal inner perimeter and the first hexagonal inner perimeter have a height therebetween in a first direction perpendicular to the first surface. The height is less than or equal to 3 microns. The third hexagonal inner perimeter and the first hexagonal inner perimeter have a width therebetween in a second direction parallel with the first surface. The width is less than or equal to 2 microns.

In one or more embodiments of the present disclosure, the third hexagonal inner perimeter is closer to the first surface than to the second surface.

In one or more embodiments of the present disclosure, the first surface and the second surface define a thickness therebetween. A range of the thickness is between 20 microns and 50 microns.

In one or more embodiments of the present disclosure, a material of the plate is iron-nickel alloy.

The above-mentioned embodiments of the present disclosure have at least the following advantages:

(1) By controlling the length of the third straight edge of the first pattern on the sheet to be less than or equal to 8 microns, and controlling the distance between the sixth straight edge and the third straight edge of the second pattern in the second direction parallel with the first surface to be larger than 5 microns and less than 30 microns inclusively, a user can form the plate of the fine metal mask in a simple and easy manner after etching the sheet, while the radius of the circular edge of the plate corresponding to a corner of the third opening is less than or equal to 15 microns.

(2) Since the radius of the circular edge corresponding to a corner of the third opening is less than or equal to 15 microns, when the fine metal mask is used in a process of evaporation in order to form pixels for displaying images on, for example, a base plate of an organic light-emitting diode (OLED) display, the shape of each of the pixels at its corner position can become clearer and sharper. Thus, the display quality of the OLED display can be effectively enhanced.

### BRIEF DESCRIPTION OF THE DRAWINGS

The disclosure can be more fully understood by reading the following detailed description of the embodiments, with reference made to the accompanying drawings as follows:

FIG. 1 is a top view of a fine metal mask according to an embodiment of the present disclosure;

FIG. 2 is a cross-sectional view along the sectional line A-A of FIG. 1;

FIG. 3 is a top view of a fine metal mask according to another embodiment of the present disclosure;

FIG. 4 is a flow diagram of a manufacturing method of a fine metal mask according to an embodiment of the present disclosure;

FIG. 5 is a schematic view of the process of the manufacturing method of the fine metal mask of FIG. 4;

FIG. 6 is a top view along the arrow B of FIG. 5;

FIG. 7 is a schematic view of a process of a manufacturing method of a fine metal mask according to another embodiment of the present disclosure;

FIG. 8 is a schematic view of the process of the manufacturing method of the fine metal mask of FIG. 4, in which the first surface is ready to be etched;

FIG. 9 is a schematic view of the process of the manufacturing method of the fine metal mask of FIG. 4, in which the etching of the first surface is completed;

FIG. 10 is a schematic view of the process of the manufacturing method of the fine metal mask of FIG. 4, in which the first opening is filled up with a resisting material and the second surface is ready to be etched; and

FIG. 11 is a schematic view of the process of the manufacturing method of the fine metal mask of FIG. 4, in which the etching of the second surface is completed.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

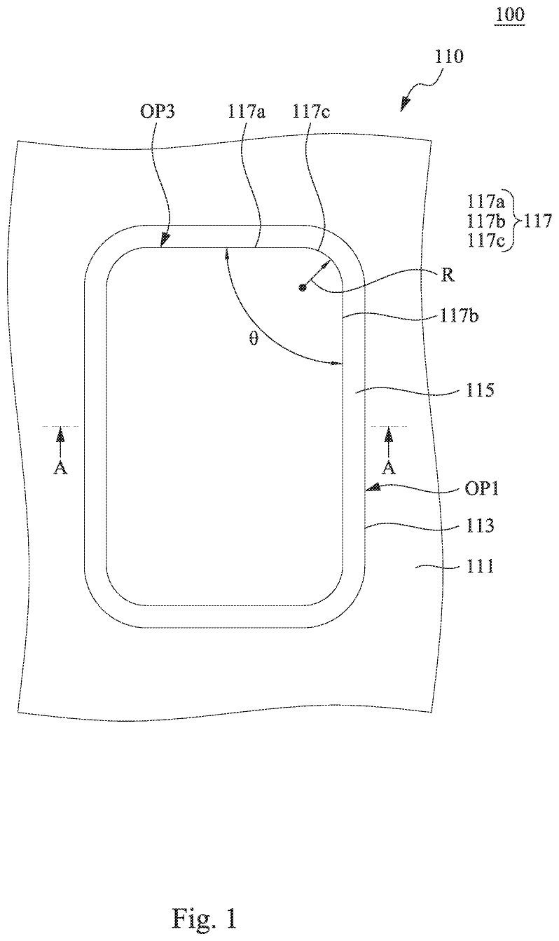

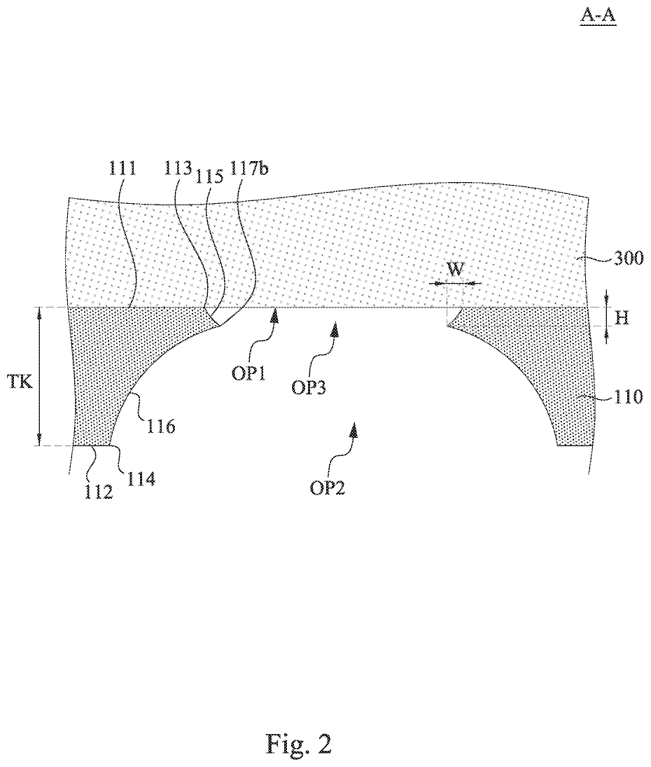

Reference is made to FIGS. 1-2. FIG. 1 is a top view of a fine metal mask 100 according to an embodiment of the present disclosure. FIG. 2 is a cross-sectional view along the sectional line A-A of FIG. 1. In this embodiment, as shown in FIGS. 1-2, a fine metal mask 100 includes a plate 110. In practical applications, the material of the plate 110 can be iron-nickel alloy. The plate 110 includes a first surface 111 and a second surface 112 opposite to the first surface 111. The first surface 111 of the plate 110 has a first inner edge 113. The first inner edge 113 surrounds and defines a first opening OP1. The second surface 112 of the plate 110 has a second inner edge 114. The second inner edge 114 surrounds and defines a second opening OP2. The second opening OP2 corresponds to and is communicated with the first opening OP1. The plate 110 further includes a first curved surface 115 and a second curved surface 116. The first curved surface 115 of the plate 110 is located inside the first opening OP1 and is connected with the first surface 111. The second curved surface 116 of the plate 110 is located inside the second opening OP2 and is connected with the second surface 112. Moreover, the plate 110 has a third inner edge 117. The first curved surface 115 and the second curved surface 116 are connected with the third inner edge 117. The third inner edge 117 surrounds and defines a third opening OP3. The third opening OP3 is smaller than the first opening OP1 and the second opening OP2. In addition, the third inner edge 117 includes a straight edge 117a, a straight edge 117b and a circular edge 117c. The straight edge 117a and the straight edge 117b together form an included angle θ. The circular edge 117c is connected between the straight edge 117a and the straight edge 117b. Thus, the circular edge 117c corresponds to a corner of the third opening OP3. It is worth to note that, in this embodiment, the circular edge 117c has a radius R. The radius R of the circular edge 117c is less than or equal to 15 microns.

Since the radius R of the circular edge 117c corresponding to a corner of the third opening OP3 is less than or equal to 15 microns, when the fine metal mask 100 is used in a process of evaporation in order to form pixels for displaying images on, for example, a base plate 300 of an organic light-emitting diode (OLED) display, the shape of each of the pixels at its corner position can become clearer and sharper. Thus, the display quality of the OLED display can be effectively enhanced.

Moreover, in this embodiment, as shown in FIG. 2, the second opening OP2 is bigger than the first opening OP1. The third inner edge 117 and the first inner edge 113 have a height H therebetween in a first direction perpendicular to the first surface 111. The height H is less than or equal to 3 microns. The third inner edge 117 and the first inner edge 113 have a width W therebetween in a second direction parallel with the first surface 111. The width W is less than or equal to 2 microns. During the process of evaporation, the plate 110 is located underneath the base plate 300 of the OLED display, and the first surface 111 of the plate 110 is configured to abut against the base plate 300 of the OLED display.

Furthermore, as shown in FIG. 2, the first surface 111 and the second surface 112 of the plate 110 define a thickness TK therebetween. A range of the thickness TK is between 20 microns and 50 microns. As mentioned above, since the height H is less than or equal to 3 microns, the third inner edge 117 is closer to the first surface 111 than to the second surface 112.

In this embodiment, as shown in FIG. 1, the third inner edge 117 is of a rectangular shape with fillet corners. This means the circular edge 117c defines the corresponding fillet corner. The included angle θ formed by the straight edge 117a and the straight edge 117b together is 90 degrees. However, this does not intend to limit the present disclosure.

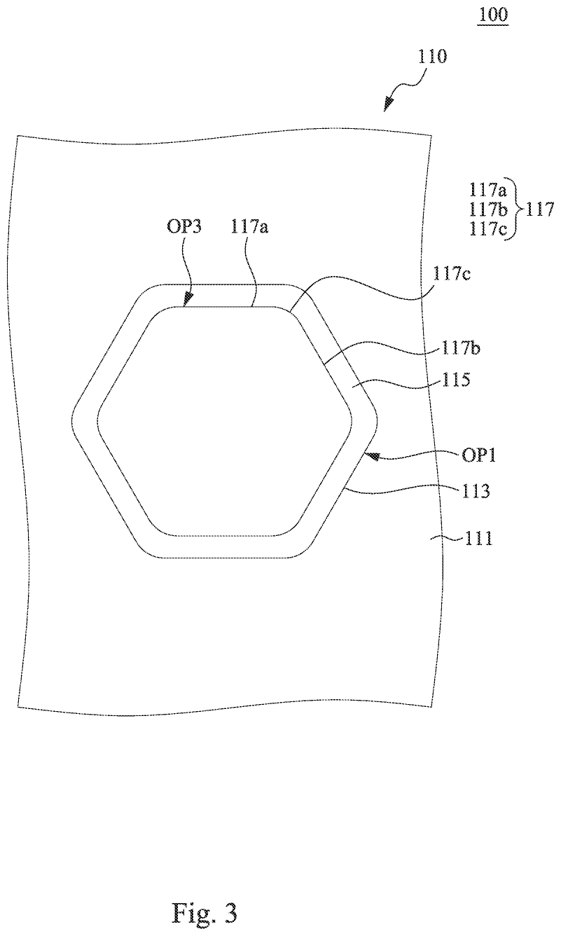

Reference is made to FIG. 3. FIG. 3 is a top view of a fine metal mask 100 according to another embodiment of the present disclosure. In this embodiment, the third inner edge 117 is of a polygonal shape. This means the included angle θ formed by the straight edge 117a and the straight edge 117b together is not equal to 90 degrees. For example, as shown in FIG. 3, the third inner edge 117 is of a hexagonal shape with fillet corners, and the circular edge 117c defines the corresponding fillet corner. However, this does not intend to limit the present disclosure. In other embodiments, according to the actual situations, the third inner edge 117 can be of an octagonal shape and any other closed geometric shapes.

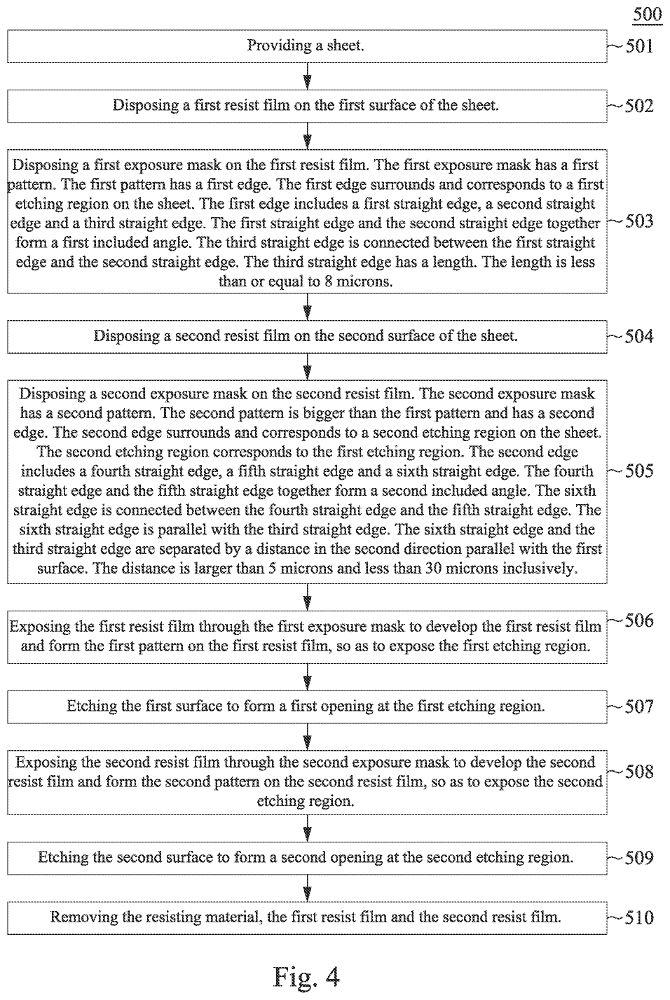

Reference is made to FIG. 4. FIG. 4 is a flow diagram of a manufacturing method 500 of a fine metal mask according to an embodiment of the present disclosure. In this embodiment, as shown in FIG. 4, a manufacturing method 500 includes the following operations (it is appreciated that the sequence of the operations and the sub-operations as mentioned below, unless otherwise specified, can all be adjusted upon the actual needs, or even executed at the same time or partially at the same time):

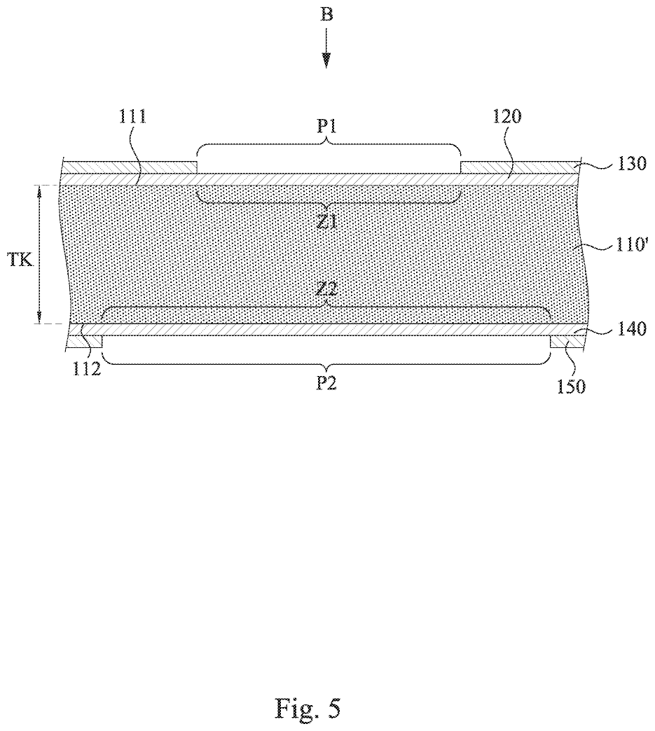

(1) Providing a sheet 110′ (Operation 501). Reference is made to FIG. 5. FIG. 5 is a schematic view of the process of the manufacturing method 500 of the fine metal mask of FIG. 4. In this embodiment, as shown in FIG. 5, the sheet 110′ includes a first surface 111 and a second surface 112 opposite to the first surface 111. The first surface 111 and the second surface 112 define a thickness TK therebetween. A range of the thickness TK is between 20 microns and 50 microns. In practical applications, the material of the sheet 110′ can be iron-nickel alloy.

(2) Disposing a first resist film 120 on the first surface 111 of the sheet 110′ (Operation 502). As shown in FIG. 5, the first resist film 120 is already disposed on the first surface 111 of the sheet 110′.

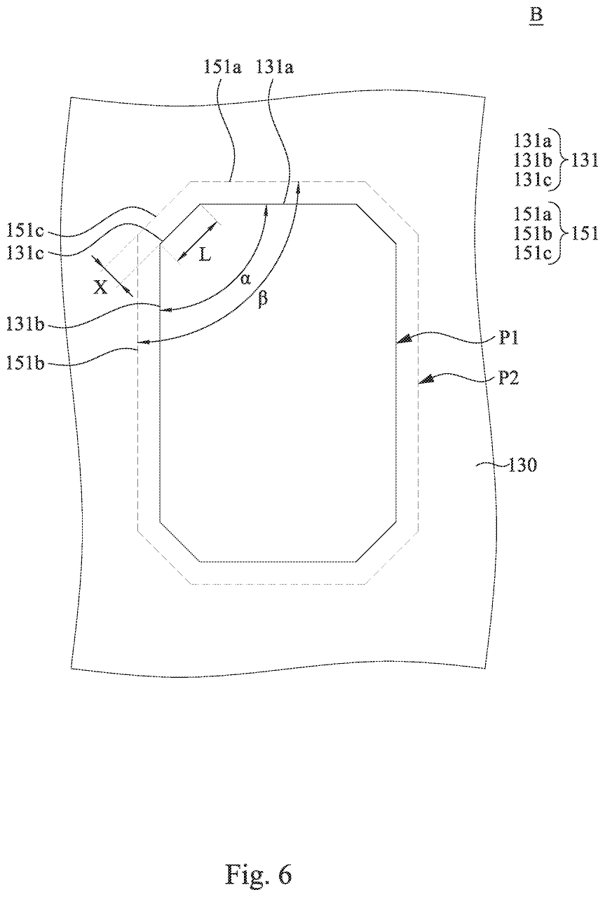

(3) Disposing a first exposure mask 130 on the first resist film 120 (Operation 503). As shown in FIG. 5, the first exposure mask 130 is already disposed on the first resist film 120, and the first resist film 120 is located between the sheet 110′ and the first exposure mask 130. Moreover, reference is made to FIG. 6. FIG. 6 is a top view along the arrow B of FIG. 5. As shown in FIG. 6, the first exposure mask 130 has a first pattern P1. For example, in this embodiment, the first resist film 120 is a positive photoresist. This means the part of the first resist film 120 exposed will dissolve in a developing solution, but the part not exposed will not dissolve in the developing solution. Therefore, the first pattern P1 is practically hollowed out on the first exposure mask 130. After the development is completed, the part of the first resist film 120 not exposed, which is not dissolved in the developing solution, will be retained on the sheet 110′, and the first pattern P1 of the first exposure mask 130 is copied to the sheet 110′ to define a first etching region Z1 to be discussed below.

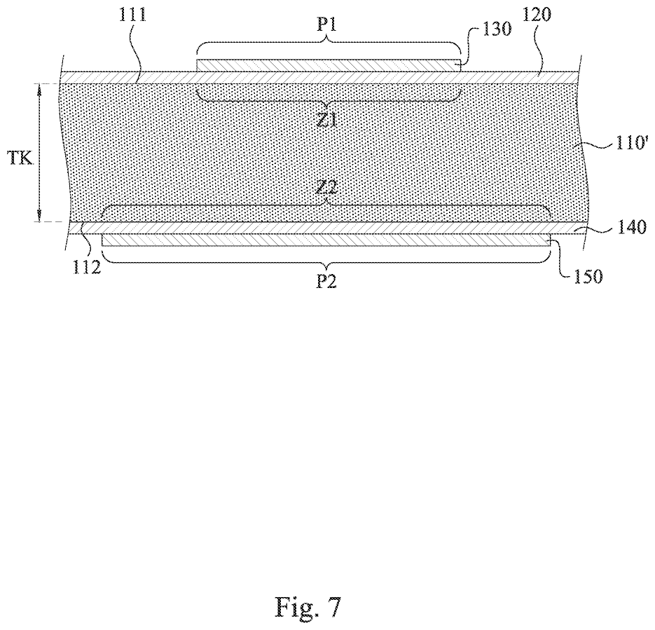

Reference is made to FIG. 7. FIG. 7 is a schematic view of a process of a manufacturing method 500 of a fine metal mask according to another embodiment of the present disclosure. In this embodiment, as shown in FIG. 7, a negative photoresist can be chosen as the first resist film 120 according to the actual situations. This means the part of the first resist film 120 exposed will not dissolve in a developing solution, but the part not exposed will dissolve in the developing solution. Therefore, the first pattern P1 is defined by the outline of the first exposure mask 130. After the development is completed, the part of the first resist film 120 exposed, which is not dissolved in the developing solution, will be retained on the sheet 110′, and the first pattern P1 of the first exposure mask 130 is copied to the sheet 110′ to define a first etching region Z1 to be discussed below.

Please go back to FIG. 6. To be more specific, the first pattern P1 has a first edge 131. The first edge 131 surrounds and corresponds to a first etching region Z1 (please refer to FIG. 5 or FIG. 7 for the first etching region Z1) on the sheet 110′. The first edge 131 includes a first straight edge 131a, a second straight edge 131b and a third straight edge 131c. The first straight edge 131a and the second straight edge 131b together form a first included angle α. The third straight edge 131c is connected between the first straight edge 131a and the second straight edge 131b. Thus, the third straight edge 131c corresponds to a corner of the first pattern P1. In this embodiment, the third straight edge 131c has a length L. The length L is less than or equal to 8 microns.

(4) Disposing a second resist film 140 on the second surface 112 of the sheet 110′ (Operation 504). As shown in FIG. 5, the second resist film 140 is already disposed on the second surface 112 of the sheet 110′. Similarly, a positive photoresist or a negative photoresist can be chosen as the second resist film 140 according to the actual situations. For the sake of easy understanding, the second resist film 140 takes a positive photoresist as an example in the subsequent descriptions.

(5) Disposing a second exposure mask 150 on the second resist film 140 (Operation 505). As shown in FIG. 5, the second exposure mask 150 is already disposed on the second resist film 140, and the second resist film 140 is located between the sheet 110′ and the second exposure mask 150. As shown in FIG. 6, the second exposure mask 150 has a second pattern P2 (since the second exposure mask 150 is blocked by the sheet 110′ in FIG. 6, the second pattern P2 is presented in hidden lines). The second pattern P2 is bigger than the first pattern P1 and has a second edge 151. The second edge 151 surrounds and corresponds to a second etching region Z2 (please refer to FIG. 5 or FIG. 7 for the second etching region Z2) on the sheet 110′. The second etching region Z2 corresponds to the first etching region Z1. The second edge 151 includes a fourth straight edge 151a, a fifth straight edge 151b and a sixth straight edge 151c. The fourth straight edge 151a and the fifth straight edge 151b together form a second included angle β. The sixth straight edge 151c is connected between the fourth straight edge 151a and the fifth straight edge 151b. Thus, the sixth straight edge 151c corresponds to a corner of the second pattern P2. Moreover, the sixth straight edge 151c is parallel with the third straight edge 131c. The sixth straight edge 151c and the third straight edge 131c are separated by a distance X in the second direction parallel with the first surface 111. It is worth to note that, in this embodiment, the distance X is larger than 5 microns and less than 30 microns inclusively.

In addition, in this embodiment, as shown in FIG. 6, the first straight edge 131a and the fourth straight edge 151a are parallel with each other, and the second straight edge 131b and the fifth straight edge 151b are also parallel with each other, such that the first included angle α is equal to the second included angle β. In other words, the first pattern P1 and the second pattern P2 have outlines of the same shape.

Furthermore, the manufacturing method 500 further includes the following operations:

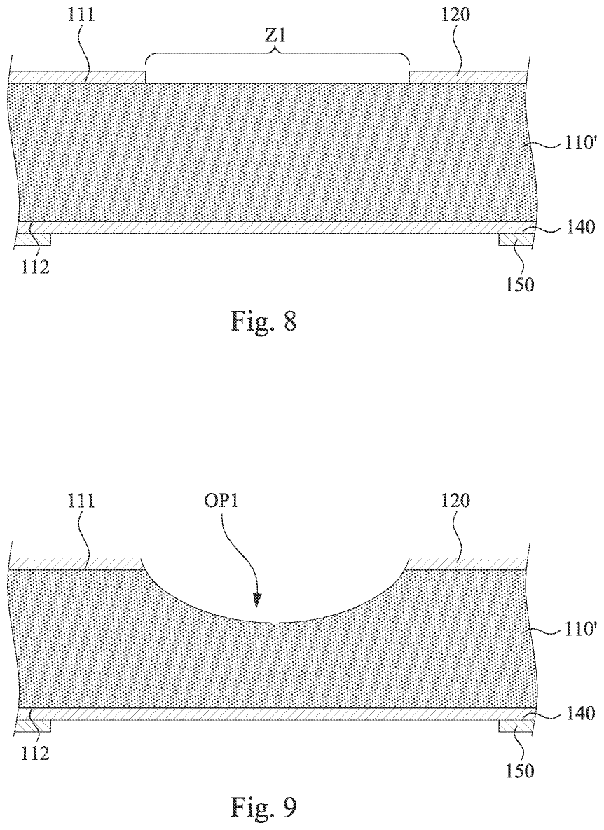

(6) Exposing the first resist film 120 through the first exposure mask 130 to develop the first resist film 120 and form the first pattern P1 on the first resist film 120, so as to expose the first etching region Z1 (Operation 506). Reference is made to FIG. 8. FIG. 8 is a schematic view of the process of the manufacturing method 500 of the fine metal mask of FIG. 4, in which the first surface 111 is ready to be etched. In this embodiment, as shown in FIG. 8, the first exposure mask 130 is already removed and the first etching region Z1 is already exposed. The first surface 111 of the sheet 110′ is ready to be etched.

(7) Etching the first surface 111 to form a first opening OP1 at the first etching region Z1 (Operation 507). Reference is made to FIG. 9. FIG. 9 is a schematic view of the process of the manufacturing method 500 of the fine metal mask of FIG. 4, in which the etching of the first surface 111 is completed. In this embodiment, as shown in FIG. 9, the first opening OP1 is already formed on the first surface 111 of the sheet 110′ by etching.

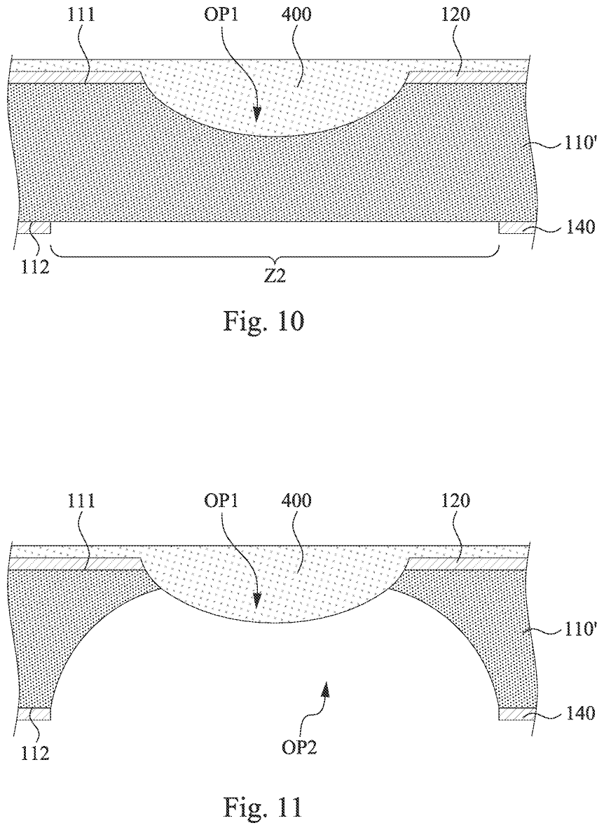

(8) Exposing the second resist film 140 through the second exposure mask 150 to develop the second resist film 140 and form the second pattern P2 on the second resist film 140, so as to expose the second etching region Z2 (Operation 508). Reference is made to FIG. 10. FIG. 10 is a schematic view of the process of the manufacturing method 500 of the fine metal mask of FIG. 4, in which the first opening OP1 is filled up with a resisting material 400 and the second surface 112 is ready to be etched. In this embodiment, as shown in FIG. 10, the second exposure mask 150 is already removed and the second etching region Z2 is already exposed. The second surface 112 of the sheet 110′ is ready to be etched. Since the first opening OP1 is filled up with the resisting material 400, the first opening OP1 will not be influenced when etching the second surface 112.

(9) Etching the second surface 112 to form a second opening OP2 at the second etching region Z2 (Operation 509). Reference is made to FIG. 11. FIG. 11 is a schematic view of the process of the manufacturing method 500 of the fine metal mask of FIG. 4, in which the etching of the second surface 112 is completed. In this embodiment, as shown in FIG. 11, the second opening OP2 is already formed on the second surface 112 of the sheet 110′ by etching.

(10) Removing the resisting material 400, the first resist film 120 and the second resist film 140 (Operation 510). After the resisting material 400 is removed, the first opening OP1 is mutually communicated with the second opening OP2. After the first resist film 120 and the second resist film 140 are removed, the sheet 110′ is formed to the plate 110 of the fine metal mask 100, as shown in FIG. 2.

By controlling the length L of the third straight edge 131c of the first pattern P1 on the sheet 110′ to be less than or equal to 8 microns, and controlling the distance X between the sixth straight edge 151c and the third straight edge 131c of the second pattern P2 in the second direction parallel with the first surface 111 to be larger than 5 microns and less than 30 microns inclusively, a user can form the plate 110 of the fine metal mask 100 in a simple and easy manner after etching the sheet 110′, while the radius R of the circular edge 117c of the plate 110 corresponding to a corner of the third opening OP3 is less than or equal to 15 microns.

In conclusion, the aforementioned embodiments of the present disclosure have at least the following advantages:

(1) By controlling the length of the third straight edge of the first pattern on the sheet to be less than or equal to 8 microns, and controlling the distance between the sixth straight edge and the third straight edge of the second pattern in the second direction parallel with the first surface to be larger than 5 microns and less than 30 microns inclusively, a user can form the plate of the fine metal mask in a simple and easy manner after etching the sheet, while the radius of the circular edge of the plate corresponding to a corner of the third opening is less than or equal to 15 microns.

(2) Since the radius of the circular edge corresponding to a corner of the third opening is less than or equal to 15 microns, when the fine metal mask is used in a process of evaporation in order to form pixels for displaying images on, for example, a base plate of an organic light-emitting diode (OLED) display, the shape of each of the pixels at its corner position can become clearer and sharper. Thus, the display quality of the OLED display can be effectively enhanced.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A fine metal mask, comprising:
a plate comprising a first surface and a second surface opposite to the first surface, the first surface having at least one first inner edge surrounding and defining a first opening, the second surface having at least one second inner edge surrounding and defining a second opening, the second opening corresponding to and communicating with the first opening, the plate further comprising at least one first curved surface and at least one second curved surface, the first curved surface being located inside the first opening and connecting with the first surface, the second curved surface being located inside the second opening and connecting with the second surface, the plate having at least one third inner edge, the first curved surface and the second curved surface connecting with the third inner edge, the third inner edge surrounding and defining a third opening, the third opening being smaller than the first opening and the second opening, the third inner edge comprising a first straight edge, a second straight edge and a circular edge, the first straight edge and the second straight edge together forming an included angle, the circular edge connecting between the first straight edge and the second straight edge, the circular edge having a radius less than or equal to 15 microns.

2. The fine metal mask of claim 1, wherein the second opening is bigger than the first opening, the third inner edge and the first inner edge have a height therebetween in a first direction perpendicular to the first surface, the height is less than or equal to 3 microns, the third inner edge and the first inner edge have a width therebetween in a second direction parallel with the first surface, the width is less than or equal to 2 microns.

3. The fine metal mask of claim 1, wherein the third inner edge is closer to the first surface than to the second surface.

4. The fine metal mask of claim 1, wherein the first surface and the second surface define a thickness therebetween, a range of the thickness is between 20 microns and 50 microns.

5. The fine metal mask of claim 1, wherein the third inner edge is of a rectangular shape.

6. The fine metal mask of claim 1, wherein the third inner edge is of a polygonal shape.

7. The fine metal mask of claim 1, wherein a material of the plate is iron-nickel alloy.

8. A method of manufacturing a fine metal mask, comprising:
providing a sheet comprising a first surface and a second surface opposite to the first surface;
disposing a first resist film on the first surface;
disposing a first exposure mask on the first resist film, the first exposure mask having at least one first pattern, the first pattern having a first edge surrounding and corresponding to a first etching region on the sheet, the first edge comprising a first straight edge, a second straight edge and a third straight edge, the first straight edge and the second straight edge together forming a first included angle, the third straight edge being connected between the first straight edge and the second straight edge, the third straight edge having a length less than or equal to 8 microns;
disposing a second resist film on the second surface; and
disposing a second exposure mask on the second resist film, the second exposure mask having at least one second pattern, the second pattern being bigger than the first pattern and having a second edge surrounding and corresponding to a second etching region on the sheet, the second etching region corresponding to the first etching region, the second edge comprising a fourth straight edge, a fifth straight edge and a sixth straight edge, the fourth straight edge and the fifth straight edge together forming a second included angle, the sixth straight edge being parallel with the third straight edge and connected between the fourth straight edge and the fifth straight edge, the sixth straight edge and the third straight edge being separated by a distance in a direction parallel with the first surface, the distance being larger than 5 microns and less than 30 microns inclusively.

9. The method of claim 8, wherein the first straight edge and the fourth straight edge are parallel with each other, the second straight edge and the fifth straight edge are parallel with each other.

10. The method of claim 8, wherein the first included angle is equal to the second included angle.

11. The method of claim 8, further comprising:
exposing the first resist film through the first exposure mask to develop the first resist film and form the first pattern on the first resist film, so as to expose the first etching region; and
exposing the second resist film through the second exposure mask to develop the second resist film and form the second pattern on the second resist film, so as to expose the second etching region.

12. The method of claim 8, further comprising:
etching the first surface to form a first opening at the first etching region; and
etching the second surface to form a second opening at the second etching region, the first opening being mutually communicated with the second opening.

13. The method of claim 12, wherein etching the second surface to form the second opening comprises:
forming an inner edge on the sheet, wherein the inner edge is closer to the first surface than to the second surface, and the inner edge surrounds and defines a third opening smaller than the first opening and the second opening.

14. The method of claim 8, wherein the first surface and the second surface define a thickness therebetween, a range of the thickness is between 20 microns and 50 microns.

15. The method of claim 8, wherein a material of the sheet is iron-nickel alloy.

16. A fine metal mask, comprising:
a plate comprising a first surface and a second surface opposite to the first surface, the first surface having at least one first hexagonal inner perimeter surrounding and defining a first opening, the second surface having at least one second hexagonal inner perimeter surrounding and defining a second opening, the second opening corresponding to and communicating with the first opening, the plate further comprising at least one first curved surface and at least one second curved surface, the first curved surface being located inside the first opening and connecting with the first surface, the second curved surface being located inside the second opening and connecting with the second surface, the plate having at least one third hexagonal inner perimeter, the first curved surface and the second curved surface connecting with the third hexagonal inner perimeter, the third hexagonal inner perimeter surrounding and defining a third opening, the third opening being smaller than the first opening and the second opening, the third hexagonal inner perimeter comprising at least one first straight edge, at least one second straight edge and at least one circular edge, the first straight edge and the second straight edge together forming an included angle of 120 degrees, the circular edge connecting between the first straight edge and the second straight edge, the circular edge having a radius less than or equal to 15 microns.

17. The fine metal mask of claim 16, wherein the second opening is bigger than the first opening, the third hexagonal inner perimeter and the first hexagonal inner perimeter have a height therebetween in a first direction perpendicular to the first surface, the height is less than or equal to 3 microns, the third hexagonal inner perimeter and the first hexagonal inner perimeter have a width therebetween in a second direction parallel with the first surface, the width is less than or equal to 2 microns.

18. The fine metal mask of claim 16, wherein the third hexagonal inner perimeter is closer to the first surface than to the second surface.

19. The fine metal mask of claim 16, wherein the first surface and the second surface define a thickness therebetween, a range of the thickness is between 20 microns and 50 microns.

20. The fine metal mask of claim 16, wherein a material of the plate is iron-nickel alloy.
